(19) United States
(12) Patent Application Publication
(10) Pub. No.: US 2017/0236588 A1
(43) Pub. Date: Aug. 17, 2017

(54) MEMORY CHIP AND OPERATING METHOD THEREOF

(71) Applicant: SK hynix Inc., Gyeonggi-do (KR)

(72) Inventors: Nam Hoon KIM, Seoul (KR); Min Kyu LEE, Chungcheongbuk-do (KR)

(21) Appl. No.: 15/214,120

(22) Filed: Jul. 19, 2016

(30) Foreign Application Priority Data
Feb. 11, 2016 (KR) 10-2016-0015697

(51) Int. Cl. G11C 16/10; G11C 16/08; G11C 16/04

(52) U.S. Cl. CPC G11C 16/10; G11C 16/0483; G11C 16/08

(57) ABSTRACT

There are provided a memory chip and an operating method thereof. A memory chip includes a main memory block including a plurality of sub-memory blocks, a peripheral circuit for programming memory cells included in the sub-memory blocks in units of pages, and a control circuit for controlling the peripheral circuit such that, after a program operation of a sub-memory block selected among the sub-memory blocks is completed, a program operation of a sub-memory block selected next among the sub-memory blocks is performed.

### CROSS-REFERENCE TO RELATED APPLICATION

The present application claims priority to Korean patent application number 10-2016-0015697 filed on Feb. 11, 2016, the disclosure of which is herein incorporated by reference in its entirety.

### BACKGROUND

1. Field

An aspect of the present disclosure relates to a memory chip and an operating method thereof, and more particularly, to an operating method of a three-dimensional memory chip.

2. Description of the Related Art

A memory device is implemented using a semiconductor such as silicon (Si), germanium (Ge), gallium arsenide (GaAs), or indium phosphide (InP). Semiconductor memory devices are generally classified into volatile memory devices and nonvolatile memory devices.

A volatile memory is a memory device which loses stored data when a power supply is cut off. The volatile memory may include a static random access memory (SRAM), a dynamic RAM (DRAM), a synchronous DRAM (SDRAM), and the like. A nonvolatile memory is a memory device which retains stored data even when a power supply is cut off. The nonvolatile memory may include a read only memory (ROM), a programmable ROM (PROM), an electrically programmable ROM (EPROM), an electrically erasable and programmable ROM (EEPROM), a flash memory, a phase-change RAM (PRAM), a magnetic RAM (MRAM), a resistive RAM (RRAM), a ferroelectric RAM (FRAM), and the like. The flash memory is generally classified into a NOR type flash memory and a NAND type flash memory.

A memory chip implemented as a flash memory may include a memory cell array for storing data, a peripheral circuit for performing program, read, and erase operations of the memory cell array, and a control circuit for controlling the peripheral circuit in response to a command.

When a memory chip is formed into a three-dimensional structure, the memory cell array may include a plurality of three-dimensional memory blocks. The three-dimensional memory blocks may include a plurality of vertical strings vertically formed from a substrate. The vertical strings may include a plurality of memory cells stacked in a vertical direction over the substrate.

The peripheral circuit may include a voltage generation circuit, a row decoder, a page buffer, a column decoder, and an input/output circuit. The voltage generation circuit may generate various operation voltages required in the program, read, and erase operations. The row decoder may transmit operation voltages to a selected memory block in response to a row address. The page buffer may transmit/receive data to/from the selected memory block and perform a data sensing operation. The column decoder may transmit data between the input/output circuit and the page buffer in response to a column address. The input/output circuit may receive a command, an address and data from an external device or output data stored in the memory chip to the external device through input/output lines. The external device may be a memory controller.

The control circuit may control the peripheral circuit in response to a command and an address.

### SUMMARY

Embodiments provide a memory chip having improved reliability and an operating method thereof.

According to an aspect of the present disclosure, there is provided a memory chip including: a main memory block configured to include a plurality of sub-memory blocks; a peripheral circuit configured to program memory cells included in the sub-memory blocks in units of pages; and a control circuit configured to control the peripheral circuit such that, after a program operation of a sub-memory block selected among the sub-memory blocks is completed, a program operation of a sub-memory block selected next among the sub-memory blocks, is performed.

According to an aspect of the present disclosure, there is provided a method of operating a memory chip, the method including: in a program operation of a main memory block selected among main memory blocks including a plurality of stacked sub-memory blocks, performing program operations of pages included in an Nth (N is a positive integer) sub-memory block among the sub-memory blocks included in the selected main memory block, the pages being respectively coupled to first to Ith (I is a positive integer) select transistor groups; and performing program operations of pages included in an (N+1)th sub-memory block among the sub-memory blocks included in the selected main memory block, the pages being respectively coupled to the first to Ith select transistor groups.

According to an aspect of the present disclosure, there is provided a method of operating a memory chip, the method including: sequentially programming memory cells included in a first string, the memory cells being coupled to first to ath word lines; sequentially programming memory cells included in a second string coupled to the same bit line as the first string, the memory cells being coupled to the first to ath word lines; sequentially programming memory cells included in the first string, the memory cells being coupled to (a+1)th to bth word lines; and sequentially programming memory cells included in the second string, the memory cells being coupled to the (a+1)th to bth word lines.

### BRIEF DESCRIPTION OF THE DRAWINGS

Example embodiments will now be described more fully hereinafter with reference to the accompanying drawings; however, they may be embodied in different forms and should not be construed as limited to the embodiments set forth herein. Rather, these embodiments are provided so that this disclosure will be thorough and complete, and will fully convey the scope of the example embodiments to those skilled in the art.

In the drawing figures, dimensions may be exaggerated for clarity of illustration. It will be understood that when an element is referred to as being “between” two elements, it can be the only element between the two elements, or one or more intervening elements may also be present. Like reference numerals refer to like elements throughout.

FIG. 1 is a diagram illustrating a memory system according to an embodiment of the present disclosure.

FIG. 2 is a diagram illustrating a memory chip of FIG. 1.

FIG. 3 is a perspective view illustrating in detail an embodiment of a main memory block of FIG. 2.

FIG. 4 is a circuit diagram illustrating in detail an embodiment of the main memory block of FIG. 2.

FIG. 5 is a flowchart illustrating a program operation according to an embodiment of the present disclosure.

FIG. 6 is a diagram illustrating a program method according to an embodiment of the present disclosure.

FIG. 7 is a diagram illustrating in detail the program method of FIG. 6.

FIG. 8 is a diagram illustrating a memory system according to an embodiment of the present disclosure.

FIG. 9 is a diagram illustrating a schematic configuration of a computing system including a memory system according to an embodiment of the present disclosure.

### DETAILED DESCRIPTION

In the following detailed description, certain exemplary embodiments of the present disclosure have been shown and described by way of illustration. As those skilled in the art would realize, the described embodiments may be modified in various different ways, all without departing from the spirit or scope of the present disclosure. Accordingly, the drawings and description are to be regarded as illustrative in nature and not restrictive.

In the entire specification, when an element is referred to as being “connected” or “coupled” to another element, it can be directly connected or coupled to the another element or be indirectly connected or coupled to the another element with one or more intervening elements interposed therebetween. In addition, when an element is referred to as “including” a component, this indicates that the element may further include another component instead of excluding another component unless stated otherwise.

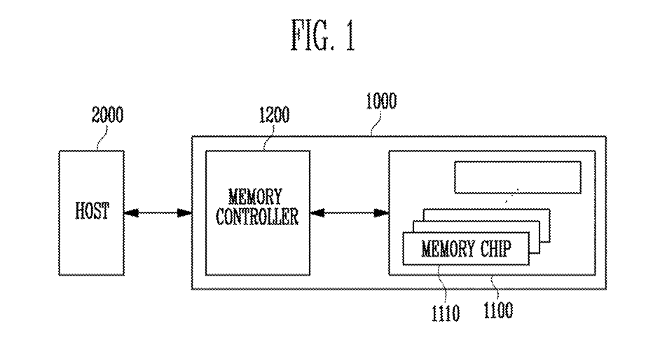

FIG. 1 is a diagram illustrating a memory system according to an embodiment of the present disclosure.

Referring to FIG. 1, the memory system 1000 may include a memory device 1100 for storing data and a memory controller 1200 for controlling the memory device 1100.

The memory device 1100 may include a plurality of memory chips 1110. The memory chips 1110 may include a double data rate synchronous dynamic random access memory (DDR SDRAM), a low power double data rate 4 (LPDDR4) SDRAM, a graphics double data rate (GDDR) SRAM, a low power DDR (LPDDR), a rambus dynamic random access memory (RDRAM), and a flash memory. In the following embodiments, the memory chip 1110 implemented as a NAND flash memory will be described as an example.

The memory controller 1200 may control overall operations of the memory device 1100. The memory controller 1200 may output to the memory device 1100, a command for controlling the memory device 1100, an address, and data, or may receive data from the memory device 1100, in response to a command received from a host 2000.

The host 2000 may communicate with the memory system 1000 by using an interface protocol such as peripheral component interconnect-express (PCI-E), advanced technology attachment (ATA), serial ATA (SATA), parallel ATA (PATA), or serial attached SCSI (SAS).

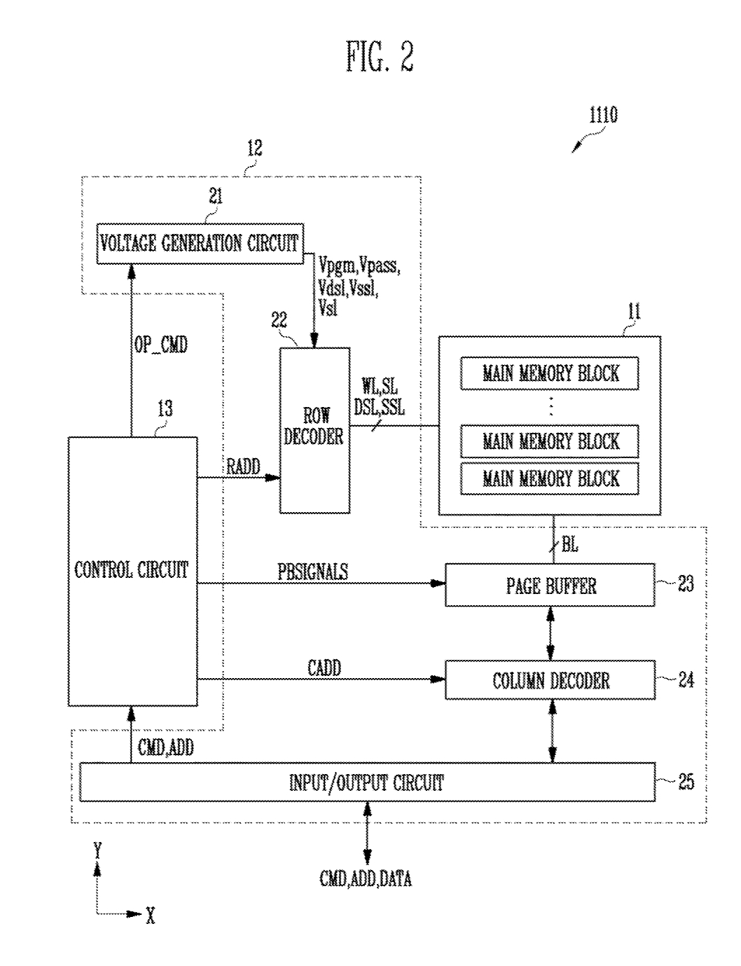

FIG. 2 is a diagram illustrating a memory chip of FIG. 1.

Referring to FIG. 2, the memory chip 1110 includes a memory cell array 11 for storing data, a peripheral circuit 12 for performing program, read and erase operations of the memory cell array 11, and a control circuit 13 for controlling the peripheral circuit 12.

The memory cell array 11 includes a plurality of main memory blocks. The main memory blocks may be configured identically to each other. The main memory blocks include a plurality of vertical strings, and the vertical strings may be formed into a three-dimensional structure. For example, the vertical strings having the three-dimensional structure may be vertically arranged over a substrate. The main memory blocks may include sub-memory blocks including a plurality of memory cells.

The peripheral circuit 12 may include a voltage generation circuit 21, a row decoder 22, a page buffer 23, a column decoder 24, and an input/output circuit 25.

The voltage generation circuit 21 may generate operation voltages having various levels in response to an operation command signal OP_CMD. The operation command signal OP_CMD may include a program command signal, a read command signal and an erase command signal. For example, the voltage generation circuit 21 may generate program voltages Vpgm, pass voltages Vpass, drain voltages Vdsl, source voltages Vssl and common source voltages Vsl, which have various levels. In addition, the voltage generation circuit 21 may generate voltages having various levels.

The row decoder 22 may select one of the main memory blocks included in the memory cell array 11 in response to a row address RADD and transmit operation voltages to word lines WL, drain select lines DSL, source select lines SSL and a source line SL, which are coupled to the selected main memory block.

The page buffer 23 is coupled to the main memory blocks through bit lines BL. The page buffer 23 may transmit/receive data to/from the selected memory block in program, read and erase operations. The page buffer 23 may arbitrarily store data transmitted from the selected memory block. During the program operation, the page buffer 23 may generate bit line voltages having various levels under control of the control circuit 13 and apply the generated bit line voltages to the bit lines BL.

The column decoder 24 may transmit data between the page buffer 23 and the input/output circuit 25 in response to a column address CADD.

The input/output circuit 25 transmits, to the control circuit 13, a command CMD and an address ADD, which are transmitted from an external device for example, the memory controller. The input/output circuit 25 outputs data DATA received from the external device to the column decoder 24. The input/output circuit 25 transmits data DATA received from the column decoder 24 to the outside or transmits the data DATA to the control circuit 13.

The control circuit 13 controls the peripheral circuit 12 to perform the program, read or erase operation in response to the command CMD and the address ADD. Particularly, during the program operation, the control circuit 13 may control the peripheral circuit 12 to perform the program operation in units of sub-memory blocks included in the selected main memory block.

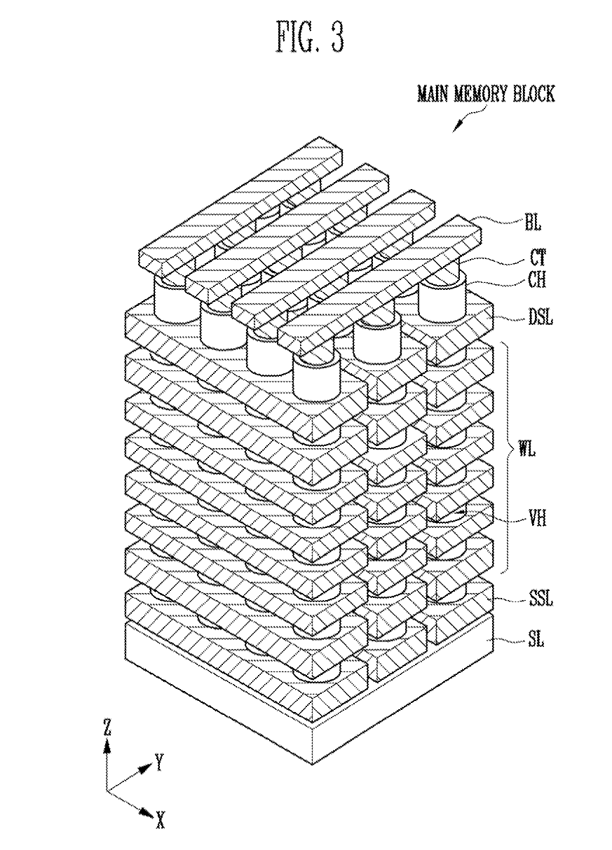

FIG. 3 is a perspective view illustrating in detail an embodiment of the main memory block of FIG. 2.

Referring to FIG. 3, the main memory block implemented in the three-dimensional structure may be formed vertically for example, in a Z direction over a substrate. The main memory block may include I-shaped vertical strings arranged between bit lines and a source line SL. This structure is also referred to as a bit cost scalable (BiCS) structure. For example, when the source line SL is horizontally formed over the substrate, the vertical strings having the BiCS structure may be formed in the vertical direction that is, the Z direction over the source line SL. More specifically, the vertical strings may include source select lines SSL, word lines WL, and drain select lines DSL, which extend in a first direction such as the X direction and are stacked spaced apart from each other. Additionally, the vertical strings may include vertical holes VH vertically penetrating the source select lines SSL, the word lines WL and the drain select lines DSL, and vertical channel layers CH formed in the vertical holes VH to contact the source line SL. Source select transistors may be formed between the vertical channel layers CH and the source select lines SSL, memory cells may be formed between the vertical channel layers CH and the word lines WL, and drain select transistors may be formed between the vertical channel layers CH and the drain select lines DSL.

The bit lines BL may be contacted with the tops of the vertical channel layers CH protruding upward from the drain select lines DSL, and may extend in a second direction such as the Y direction, perpendicular to the first direction that is, the X direction. Contact plugs may be further formed between the bit lines BL and the vertical channel layers CH. The main memory blocks may be formed into various structures as well as the above-described BiCS structure.

FIG. 4 is a circuit diagram illustrating in detail an embodiment of the main memory block of FIG. 2.

Referring to FIG. 4, the main memory block having the three-dimensional structure may include a plurality of vertical strings ST. The vertical strings ST may be coupled between bit lines BL1 to BLk where k is a positive integer, and a source line SL. In FIG. 4, the vertical strings ST are formed in an ‘I’ shape, but may be formed in a ‘U’ shape depending on a memory chip.

The vertical strings ST may be arranged in a matrix form along a first direction (X direction) and a second direction (Y direction). The vertical strings ST may include source select transistors SST, a plurality of memory cells F1 to Fn where n is a positive integer, and drain select transistors DST. The source select transistors SST may be coupled between the source line SL and the memory cells F1, and the drain select transistors DST may be coupled between the bit lines BL1 to BLk where k is a positive integer and the memory cells Fn. Gates of the source select transistors SST may be commonly coupled to a source select line SSL. Gates of the memory cells F1 to Fn may be coupled to word lines WL1 to WLn, respectively. Memory cells arranged in different layers along a third direction (Z direction) among the memory cells F1 to Fn may be coupled to different word lines, and memory cells arranged in the same layer along the first and second directions (X and Y directions) may be commonly coupled to the same word line. A group of memory cells arranged along the first direction (X direction) may be referred to as a page. Gates of the drain select transistors DST are coupled to drain select lines DSL1 to DSL3, respectively. Drain select transistors DST coupled to the same bit line among the drain select transistors DST may be coupled to different drain select lines DSL1 to DSL3, respectively. Drain select transistors DST coupled along the first direction (X direction) among the drain select transistors coupled to different bit lines BL1 to BLk may be commonly coupled to each of the drain select lines DSL1 to DSL3. The number of drain select lines is not limited to that of the drain select lines shown in FIG. 4, and may be changed depending on a memory chip.

When the bit lines BL1 to BLk are arranged spaced part from each other in the first direction (X direction) and extend in the second direction (Y direction), the vertical strings ST may be coupled to the bit lines BL1 to BLk along the first direction (X direction), respectively. A plurality of vertical strings ST may be coupled to each of the bit lines BL1 to BLk along the second direction (Y direction).

The main memory block may include a plurality of sub-memory blocks divided along the third direction (Z direction). The sub-memory blocks may include memory cells coupled to a plurality of word lines.

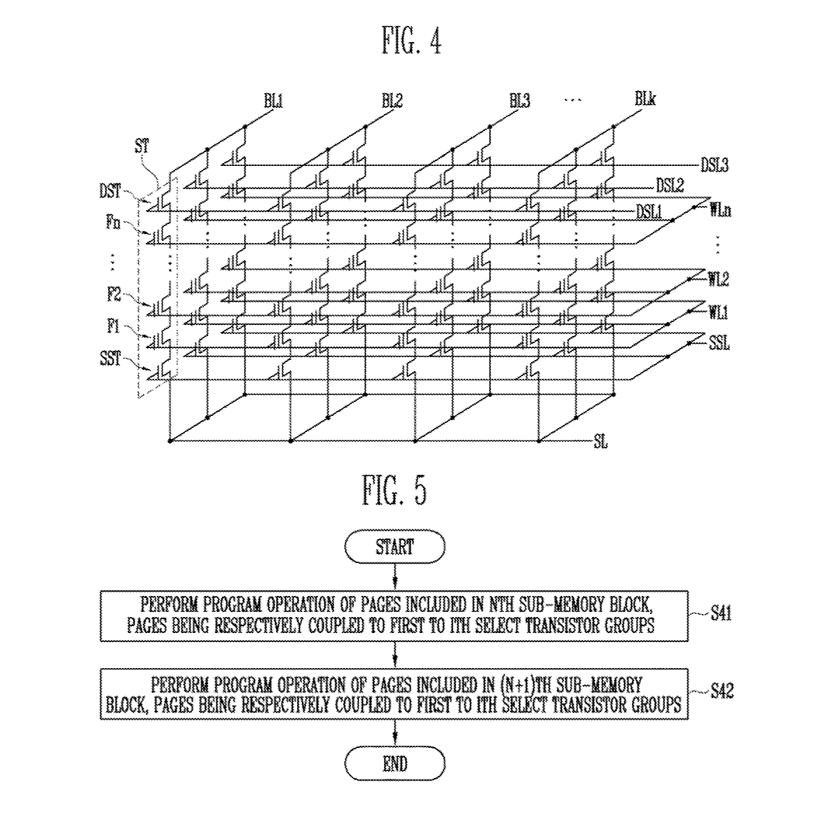

FIG. 5 is a flowchart illustrating a program operation according to an embodiment of the present disclosure.

Referring to FIG. 5, the program operation may be performed in units of sub-memory blocks. For example, the program operation may be performed to pages included in an Nth sub-memory block where N is a positive integer, the pages being respectively coupled to first to Ith select transistor groups where I is a positive integer (S41). Subsequently, the program operation may be performed to pages included in an (N+1)th sub-memory block, the pages being respectively coupled to the first to Ith select transistor groups (S42). The select transistor groups may be drain select transistor groups.

For example, drain select transistors arranged in a first direction (X direction) may be defined as first select transistor group, and drain select transistors adjacent to the first select transistor group in a second direction (Y direction) may be defined as a second select transistor group. A program operation is performed to a sub-memory block selected among the sub-memory blocks coupled to the first select transistor group, and then performed to a sub-memory block selected among the sub-memory blocks coupled to the second select transistor group.

When the program operation to the selected sub-memory block coupled to the second select transistor group is completed, the program operation is again performed to a sub-memory block newly selected among the sub-memory blocks coupled to the first select transistor group.

That is, the program operations can be alternately performed to the sub-memory blocks coupled to the first select transistor group and the sub-memory blocks coupled to the second select transistor group.

The above-described program operation will be described in detail as follows.

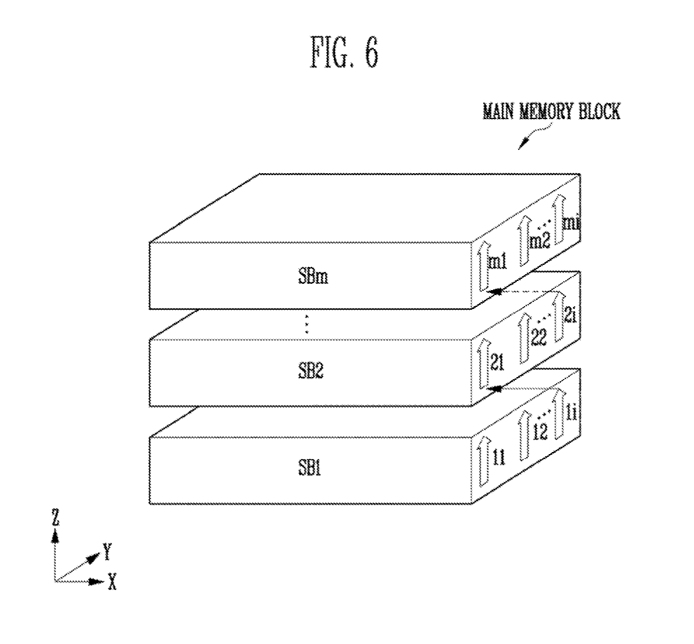

FIG. 6 is a diagram illustrating a program method according to an embodiment of the present disclosure.

Referring to FIG. 6, the memory cells included in the main memory block may be divided into a plurality of sub-memory blocks. For example, when the main memory block includes first to mth sub-memory blocks SB1 to SBm where m is a positive integer, each of the first to mth sub-memory blocks SB1 to SBm may include a plurality of memory cells coupled to a plurality of word lines. The memory cells included in each of the first to mth sub-memory blocks SB1 to SBm may be memory cells arranged in a first direction (X direction), a second direction (Y direction), and a third direction (Z direction).

The program operation to the main memory block may be performed in an order from the first sub-memory block SB1 to the mth sub-memory block SBm. In each sub-memory block, the program operation to the memory cells may be performed in units of drain select transistor groups. The respective drain select transistor groups may include drain select transistors arranged in the first direction. The program operation may be performed to the memory cells arranged in the first direction and coupled to the respective drain select transistor groups in units of pages.

When the memory cells coupled to one drain select transistor group are divided into N pages where N is a positive integer, for each sub-memory block, first to Nth pages may be coupled to respective drain select transistor groups in the respective first to mth sub-memory blocks SB1 to SBm.

The program operation to the main memory block will be described in detail. For example, the program operation may be firstly performed to the first sub-memory block SB1. The program operation may be sequentially performed to a first page group 11 of first to Nth pages coupled to the first drain select transistor group in the first sub-memory block SB1. When program operations to the first page group 11 of the first to Nth pages coupled to the first drain select transistor group in the first sub-memory block SB1 are all completed, the program operations may be sequentially performed to a second page group 12 of first to Nth pages coupled to a second drain select transistor group in the first sub-memory block SB1. In this manner, the program operations may be sequentially performed to first to ith page groups 11 to 1i where “i” is a positive integer of first to Nth pages coupled to the respective first to ith drain select transistor groups in the first sub-memory block SB1.

When the program operation to the first sub-memory block SB1 is completed, then the program operations may be performed to the second sub-memory block SB2. In the second sub-memory block SB2, the program operations may be sequentially performed to first to ith page groups 21 to 21 of first to Nth pages coupled to the respective first to ith drain select transistor groups in a similar way to the program operations to first to Ith page groups 11 to 1i of first to Nth pages coupled to the respective first to ith drain select transistor groups in the first sub-memory block SB1.

Therefore, the program operations may be sequentially performed to the first to mth sub-memory block SB1 to SBm in the main memory block.

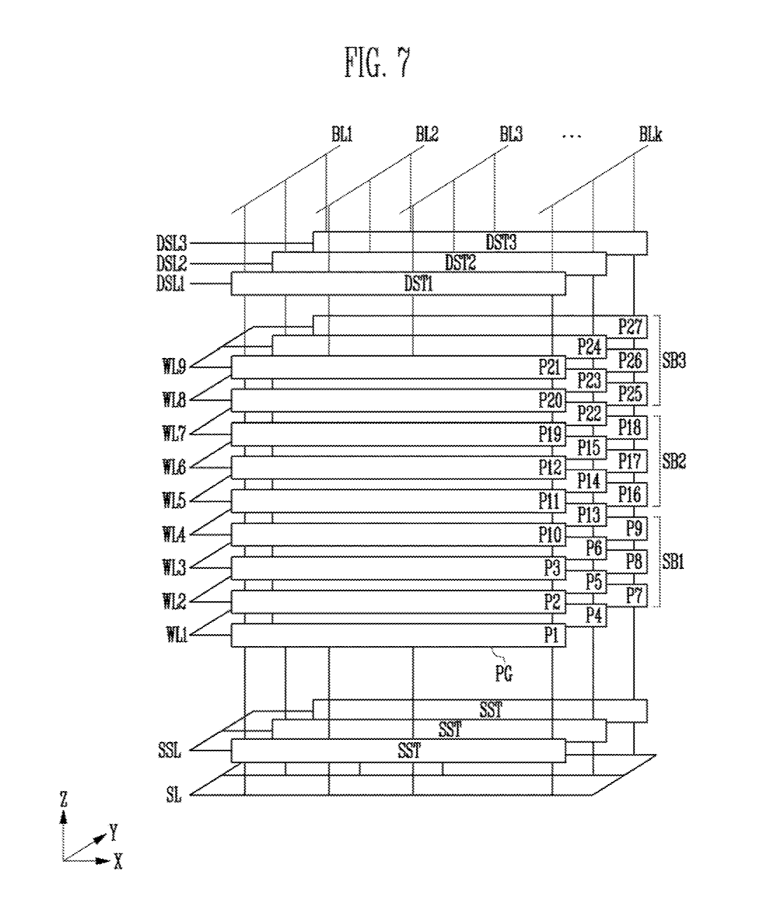

As described above, a plurality of sub-memory blocks and a plurality of drain select transistor groups may be included in one main memory block depending on a memory chip. The above-described program operation having a program operation of a main memory block including three drain select transistor groups that is, i=3 and three sub-memory blocks that is, m=3 coupled to each of the drain select transistor groups, the sub-memory blocks each having three pages that is, N=3 coupled thereto, will be described with reference to FIG. 7.

FIG. 7 is a diagram illustrating in detail the program method of FIG. 6.

Referring to FIG. 7, each main memory block may include a plurality of sub-memory blocks coupled to a plurality of drain select transistor groups. In FIG. 7, the program operation of the main memory block including first to third drain select transistor groups DST1 to DST3 and first to third sub-memory blocks SB1 to SB3 coupled to each of the first to third drain select transistor groups DST1 to DST3 will be described as an example.

The first drain select transistor group DST1 may be a group of drain select transistors commonly coupled to a first drain select line DSL1, the second drain select transistor group DST2 may be a group of drain select transistors commonly coupled to a second drain select line DSL2, and the third drain select transistor group DST3 may be a group of drain select transistors commonly coupled to a third drain select line DSL3. That is, the first to third drain select transistor groups DST1 to DST3 may selectively operate according to voltages applied to the first to third drain select lines DSL1 to DSL3. First to kth bit lines BL1 to BLk may be coupled to drains of the first to third drain select transistor groups DST1 to DST3. For example, drain select transistors adjacent in the second direction (Y direction) among the first to third drain select transistor groups DST1 to DST3 may be coupled to the same bit line.

Source select transistors SST may be commonly coupled to a source select line SSL. Therefore, the source select transistors SST may commonly operate according to a voltage applied to the source select line SSL. Sources of the source select transistors SST may be commonly coupled through a source line SL.

The first to third sub-memory blocks SB1 to SB3 may include a plurality of memory cells coupled between the source select transistors SST and the first to third drain select transistor groups DST1 to DST3. Gates of memory cells arranged in the same layer may be coupled to the same word line, and gates of memory cells arranged in different layers may be coupled to different word lines. For example, gates of memory cells arranged directly over the source select transistors SST may be commonly coupled to a first word line WL1.

Among the memory cells coupled to the first word line WL1, a group of memory cells coupled to the same drain select transistor group becomes a page (PG). Therefore, in the first sub-memory block SB1, a first page group of first to third pages P1 to P3, a second page group of first to third pages P4 to P6 and a third page group of first to third pages P7 to P9 may be coupled to the first to third drain select transistor groups DST1 to DST3, respectively. Additionally, in the second sub-memory block SB2, a first page group of first to third pages P10 to P12, a second page group of first to third pages P13 to P15 and a third page group of first to third pages P16 to P18 may be coupled to the first to third drain select transistor groups DST1 to DST3, respectively. Further, in the third sub-memory block SB2, a first page group of first to third pages P19 to P21, a second page group of first to third pages P22 to P24 and a third page group of first to third pages P25 to P27 may be coupled to the first to third drain select transistor groups DST1 to DST3, respectively.

In the first sub-memory block SB1, the firstly ordered pages such as, the first pages P1, P4 and P7 of the respective first to third page groups may be adjacent to the source select transistors SST while the lastly ordered pages such as, the third pages P3, P6 and P9 of the respective first to third page groups may be respectively adjacent to the respective first to third drain select transistor groups DST1 to DST3, as well as the second and third sub-memory blocks SB2 and SB3.

A program operation of the main memory block including the above-described configuration will be described in detail as follows.

The program operations may be sequentially performed from the first to third pages P1 to P3 of the first page group coupled to the first drain select transistor group DST1 of the first sub-memory block SB1.

When the program operations to the first to third pages P1 to P3 of the first page group coupled to the first drain select transistor group DST1 are completed, the program operations may be sequentially performed from the first to third pages P4 to P6 of the second page group coupled to the second drain select transistor group DST2 of the first sub-memory block SB1. The program operation may be performed using an incremental step pulse program (ISPP) method. When a program voltage is applied to the selected word lines W1 to W3, a pass voltage lower than the program voltage may be applied to the other unselected word lines W4 to W9. The program voltage and the pass voltage may be set to positive voltages higher than 0V.

To select pages of the respective first to third page groups respectively coupled to the first to third drain select transistor groups DST1 to DST3, voltages applied to the first to third drain select transistor lines DSL1 to DSL3 may be adjusted. For example, to perform the program operations to the pages P1 to P3 of the first page group coupled to the first drain select transistor group DST1, a turn-off voltage may be applied to the second and third drain select lines DSL2 and DSL3, and a turn-on voltage may be applied to the first drain select line DSL1. Therefore, only the drain select transistors included in the first drain select transistor group DST1 may be turned on, and the drain select transistors included in the other second and third drain select transistor groups DST2 and DST3 may be turned off.

Accordingly, a program permission voltage such as, 0V or a program prohibition voltage such as, VCC applied to the first to kth bit lines BL1 to BLk can be transmitted to channels of vertical strings coupled to the first drain select transistor group DST1.

When the program operations to the first to third pages P4 to P6 of the second page group coupled to the second drain select transistor group DST2 of the first sub-memory block SB1 are completed, the program operations may be sequentially performed to the first to third pages P7 to P9 of the third page group coupled to the third drain select transistor group DST3 of the first sub-memory block SB1.

When the program operations to the first to third pages P7 to P9 of the third page group coupled to the third drain select transistor group DST3 of the first sub-memory block SB1 are completed, the program operations may be sequentially performed to the first to third pages P10 to P12 of the first page group coupled to the first drain select transistor group DST1 of the second sub-memory block SB2. When the program operations to the first to third pages P10 to P12 of the first page group coupled to the first drain select transistor group DST1 of the second sub-memory block SB2 are completed, the program operations may be sequentially performed to the first to third pages P13 to P15 of the second page group coupled to the second drain select transistor group DST2 of the second sub-memory block S82. When the program operations to the first to third pages P13 to P15 of the second page group coupled to the second drain select transistor group DST2 of the second sub-memory block SB2 are completed, the program operations may be sequentially performed to the first to third pages P16 to P18 of the third page group coupled to the third drain select transistor group DST3 of the second sub-memory block SB2.

When the program operations to the first to third pages P16 to P18 of the third page group coupled to the third drain select transistor group DST3 of the second sub-memory block SB2 are completed, the program operations may be sequentially performed to the first to third pages P19 to P21 of the first page group coupled to the first drain select transistor group DST1 of the third sub-memory block SB3. When the program operations to the first to third pages P19 to P21 of the first page group coupled to the first drain select transistor group DST1 of the third sub-memory block SB3 are completed, the program operations may be sequentially performed to the first to third pages P22 to P24 of the second page group coupled to the second drain select transistor group DST2 of the third sub-memory block SB3. When the program operations to the first to third pages P22 to P24 of the second page group coupled to the second drain select transistor group DST2 of the third sub-memory block SB3 are completed, the program operations may be sequentially performed to the first to third pages P25 to P27 of the third page group coupled to the third drain select transistor group DST3 of the third sub-memory block SB3.

As such, the program operations may be sequentially performed to the first to third page groups respectively coupled to the first to third drain select transistor groups of the respective first to third sub-memory blocks SB1 to SB3 in the main memory block. That is, pages coupled to different drain select transistor groups are sequentially programmed, so that it is possible to prevent a decrease in channel voltage in the vicinity of unselected memory cells, thereby suppressing program disturb deterioration of the unselected memory cells. Thus, it is possible to improve the reliability of the memory chip.

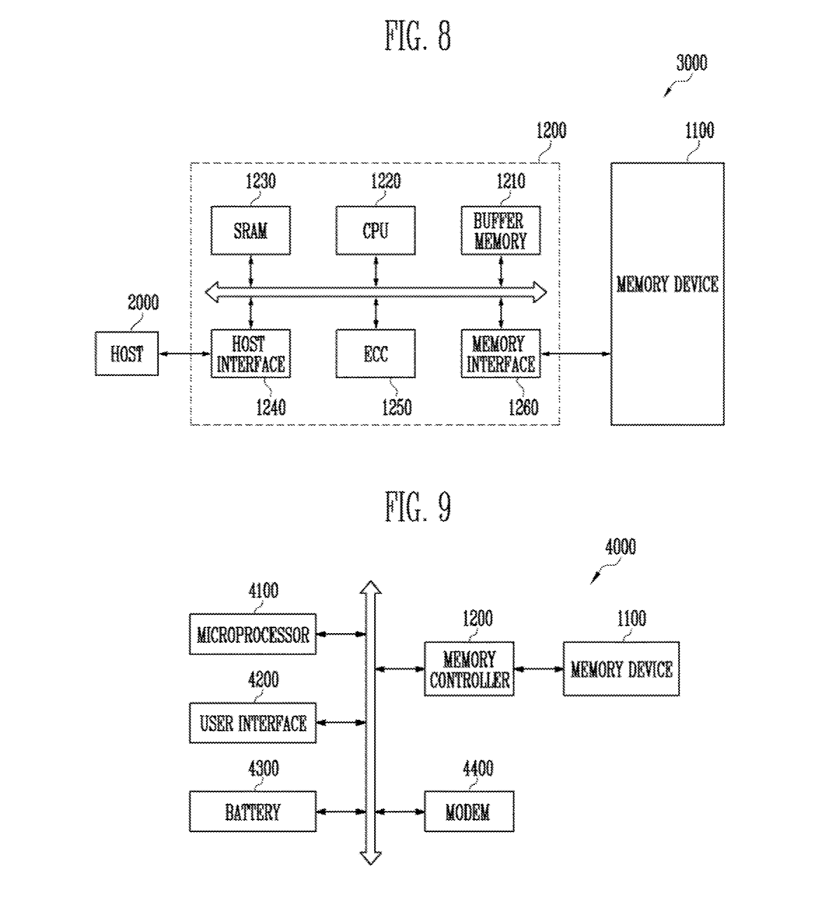

FIG. 8 is a diagram illustrating a memory system according to an embodiment of the present disclosure.

Referring to FIG. 8, the memory system 3000 may include a memory device 1100 for storing data and a memory controller 1200 for controlling the memory device 1100. Furthermore, the memory controller 1200 controls communication between a host 2000 and the memory device 1100. The memory controller 1200 may include a buffer memory 1210, a CPU 1220, an SRAM 1230, a host interface 1240, an ECC 1250 and a memory interface 1260.

The buffer memory 1210 temporarily stores data while the memory controller 1200 controls the memory device 1100. The CPU 1220 may perform a control operation for data exchange of the memory controller 1200. The SRAM 1230 may be used as a working memory of the CPU 1220. The host interface 1240 may be provided with a data exchange protocol of the host 2000 coupled to the memory system 3000. The ECC 1250 is an error correction unit, and may detect and correct errors included in data read out from the memory device 1100. The semiconductor interface 1260 may interface with the memory device 1100. Although not shown in FIG. 8, the memory system 3000 may further include a ROM (not shown) for storing code data for interfacing with the host 2000.

The host 2000 for which the memory system 3000 is available may include a computer, a ultra mobile PC (UMPC), a workstation, a net-book, a personal digital assistant (PDA), a portable computer, a web tablet, a wireless phone, a mobile phone, a smart phone, a digital camera, a digital audio recorder, a digital audio player, a digital video recorder, a digital video player, a device capable of transmitting/receiving information in a wireless environment, and one of various electronic devices that constitute a home network.

FIG. 9 is a diagram illustrating a schematic configuration of a computing system including a memory system according to an embodiment of the present disclosure.

Referring to FIG. 9, the computing system 4000 may include a memory device 1110, a memory controller 1200, a microprocessor 4100, a user interface 4200, and a modem 4400, which are electrically coupled to a bus. When the computing system 4000 is a mobile device, a battery 4300 for supplying operation voltages of the computing system 4000 may be additionally provided in the computing system 4000. Although not shown in this figure, the computing system 4000 may further include an application chip set, a camera image processor (CIS), a mobile DRAM, and the like. The memory controller 1200 and the memory device 1110 may constitute a solid state drive/disk (SSD).

The computing system 4000 may be packaged in various forms. For example, the computing system 4000 may be packaged in a manner such as package on package (PoP), ball grid arrays (BGAs), chip scale packages (CSPs), plastic leaded chip carrier (PLCC), plastic dual in-line package (PDIP), die in Waffle pack, die in wafer form, chip on board (COB), ceramic dual in-line package (CERDIP), plastic metric quad flat pack (MQFP), thin quad flat pack (TQFP), small outline integrated circuit (SOIC), shrink small out line package (SSOP), thin small outline package (TSOP), thin quad flat pack (TQFP), system in package (SIP), multi chip package (MCP), wafer-level fabricated package (WFP), or wafer-level processed stack package (WSP).

According to the present disclosure, it is possible to improve the reliability of the memory chip.

Example embodiments have been disclosed herein, and although specific terms are employed, they are used and are to be interpreted in a generic and descriptive sense only and not for purpose of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope of the present disclosure as set forth in the following claims.

1. A memory chip comprising:
a main memory block including a plurality of sub-memory blocks each including at least two pages, wherein the sub-memory blocks are coupled between drain select transistor groups and source select transistor groups;
a peripheral circuit suitable for programming memory cells included in the sub-memory blocks in units of pages; and
a control circuit suitable for controlling the peripheral circuit to sequentially perform program operations on pages coupled to a drain select transistor group coupled to a drain select line in a selected sub-memory block among the sub-memory blocks, and sequentially perform program operations on pages coupled to another drain select transistor group coupled to another drain select line in the selected sub-memory block when the program operations on the pages coupled to the drain select transistor group in the selected sub-memory block are completed.

2. The memory chip of claim 1, wherein the sub-memory blocks are arranged between drain select transistor groups and source select transistors.

3. The memory chip of claim 2,
wherein each of the drain select transistor groups includes drain select transistors coupled to a drain select line, and
wherein the drain select transistor groups are coupled to drain select lines, respectively.

4. The memory chip of claim 2, wherein the respective pages include memory cells coupled to a word line and one among the drain select transistor groups.

5. The memory chip of claim 4,
wherein the plurality of pages included in the respective sub-memory blocks are divided into a plurality of page groups respectively coupled to the drain select transistor groups, and
wherein the control circuit controls the peripheral circuit to perform the program operations to the plurality of page groups in sequence in a selected sub-memory block.

6. A method of operating a memory chip including sub-memory blocks arranged in a first direction each including page groups arranged in the first direction and a second direction, the method comprising:
performing program operations on page groups arranged in the first direction and page groups disposed next to each other in the second direction and arranged in the first direction, wherein the page groups are included in an m^{th} sub-memory block; and
performing program operations on page groups arranged in the first direction and page groups disposed next to each other in the second direction and arranged in the first direction, wherein the page groups are included in an (m+1)^{th} sub-memory block.

7. The method of claim 6,
wherein each of the page groups arranged in the first direction is coupled to the same drain select transistor group coupled to a drain select line, and
wherein each of the page groups arranged in the second direction is coupled to another drain select transistor group coupled to another drain select line.

8. The method of claim 6, wherein the program operations on the page groups included in the (m+1)^{th} sub-memory block are performed after the program operations on the page groups included in the m^{th} sub-memory block are performed.

9. The method of claim 8, wherein the program operations in the (m+1)^{th} sub-memory block are performed in the same order as the program operations performed in the m^{h} sub-memory block.

10. A method of operating a memory chip including at least two sub-memory blocks each including at least two page groups, the method comprising:
performing a first program operation to a first page group included in a first sub-memory block and coupled to a first drain select transistor group;
performing a second program operation to a second page group included in the first sub-memory block and coupled to a second drain select transistor group after the performing of the first program operation;
performing a third program operation to a first page group included in a second sub-memory block and coupled to the first drain select transistor group after the performing of the second program operation; and
performing a fourth program operation to a second page group included in the second sub-memory block and coupled to the second drain select transistor group after the performing of the third program operation.

11. (canceled)

12. The method of claim 10, wherein the respective first and second page groups include memory cells coupled to a word line and one among the first and second drain select transistor groups.

13. A method of operating a memory chip, the method comprising:
sequentially programming memory cells included in first to A^{th} page groups coupled to a first drain select transistor group;
sequentially programming memory cells included in first to A^{th} page groups coupled to a second select transistor group;
sequentially programming memory cells included in (A+1)^{th} to B^{th} page groups coupled to the first drain select transistor group; and
sequentially programming memory cells included in (A+1)^{th} to B^{th} page groups coupled to the second select transistor group.

14. The method of claim 13, wherein, when a program voltage is applied to a selected word line coupled to a selected page group among the page groups, a pass voltage is applied to the other word lines.

15. The method of claim 13, wherein the programming of the memory cells is performed using an incremental step pulse program (ISPP) method.

16. (canceled)

17. The method of claim 13,
wherein each of the first and second drain select transistor groups includes drain select transistors coupled to a drain select line, and
wherein the first and second drain select transistor groups are coupled to first and second drain select lines, respectively.

18. The method of claim 13, wherein the sequential programming of the memory cells is performed in stack order of the memory cells.

19. The method of claim 13, wherein A and B are positive integers, and B is greater than A.

20. (canceled)
